(19) United States
(12) Patent Application Publication
(10) Pub. No.: US 2007/0127599 A1
(43) Pub. Date: Jun. 7, 2007

(54) Apparatus and method for phase recovery and I/Q imbalance compensation in quadrature demodulating receiver

(76) Inventors: Yung-Jeong Song, Daejon (KR); Deock-Gil Oh, Daejon (KR); Ho-Jin Lee, Daejon (KR)

Correspondence Address: LADAS & PARRY LLP, 224 SOUTH MICHIGAN AVENUE, SUITE 1600, CHICAGO, IL, 60604, US

(21) Appl. No.: 11/605,646

(22) Filed: Nov. 29, 2006

(30) Foreign Application Priority Data
Dec. 1, 2005 (KR) 10-2005-0116154
Jul. 25, 2006 (KR) 10-2006-0069954

(51) Int. Cl. H04L 27/00; H03D 1/04

(52) U.S. Cl. 375/326; 375/346

(57) ABSTRACT

An apparatus and method for phase recovery and I/O imbalance compensation in a quadrature demodulating receiver are provided. The apparatus includes: a phase error compensating unit for compensating a phase error for a reference channel which is one of the I channel and the Q channel; and a phase imbalance compensation unit for compensating a phase imbalance between the reference channel and a target channel that is the other of the I channel and the Q channel for the target channel based on the reference channel that is the phase error compensated channel at the phase error compensating unit.

### FIELD OF THE INVENTION

The present invention relates to an apparatus and method for phase recovery and I/Q imbalance compensation in a quadrature demodulating receiver; and, more particularly, to an apparatus and method for carrier wave phase recovery and I/Q imbalance compensation in a quadrature demodulating receiver in order to increase the utilization level of wireless communication with a simple structure by integrally embodying the carrier wave recovery function and the I/Q phase imbalance compensation function by firstly compensating one of channels, for example, I-channel, and then compensating the other based on the firstly compensated channel.

### DESCRIPTION OF RELATED ARTS

In a high speed wireless communication system, a received signal through an antenna is demodulated through a RF block and an IF block for restoring an original signal from the received signal. In order to obtained desired signals from each of processing blocks that process the received signal from the antenna, the signal is processed through frequency-down conversion and signal amplification.

In order to perform the frequency-down conversion and the signal amplification, the radio frequency (RF) block and the intermediate frequency (IF) block use various analog elements such as mixers and amplifiers. Such analog elements deteriorate the input signal due to the insulating property between elements and the instable orthogonal property although the analog elements satisfy the high-level specifications.

One of major factors that deteriorate the input signal is the imbalance between I/Q channels. The I/Q channels are imbalanced because the analog elements are not perfectly insulated from one another and a signal cannot be generated to have a perfect 90° phase difference between the I/Q channels. The imbalance between I/Q channels becomes a factor to degrade the performance of the demodulator in a MODEM. Therefore, a method of removing the imbalance between I/Q channels has been required.

In order to remove the imbalance between I/Q channels, various methods were introduced, for example, a RF direct conversion receiver.

A conventional method for compensating a gain and phase imbalance using a plurality of complex adders, multipliers and counters in a demodulator was introduced in U.S. Pat. No. 6,044,122 entitled “Methods and apparatus for correcting amplitude and phase imbalance in demodulators,” invented by Johua L. Koslov, issued at Mar. 28, 2000 to Hitachi America. In this conventional method, the complexity thereof is higher than others due to a plurality of complex number multipliers. Also, it is sensitive to the noise in a demodulator because it is embodied using a simple counter. Furthermore, since the imbalance level between the I/Q channels is set according to the increment and decrement of the counter, the response speed thereof varies in this conventional apparatus and method. That is, the form of a receiving signal is decided by the gap between the increment and decrement of the counter without reflecting the form of the real receiving signal.

Another related art was introduced in U.S. Pat. No. 5,949,821 entitled “Method and apparatus for correcting phase and gain imbalance between in-phase (I) and Quadrature (Q) components of a received signal based on a determination of peak amplitudes” invented by Shahriar Emami, and issued at Sep. 7, 1999 to Motorola, Inc. In this conventional method and apparatus, an amplitude peak of the demodulated I channel and Q channel is detected, and the imbalance between an I channel and a Q channel is corrected using the detected amplitude peak. Herein, one of the I/Q channels is set as a reference channel, and the other is set as an imbalance channel. Then, the amplitude peak of each channel is obtained and the phase imbalance is obtained using a sine function. As described above, the conventional method and apparatus is a method of obtaining a phase imbalance between the I/Q channels and uses arc sine function. However, the arc sine function increases a circuit complexity and the accuracy thereof when it is embodied as a digital circuit.

In a conventional quadrature demodulating receiver, a phase error correcting circuit and an I/O channel phase imbalance correcting circuit are formed separately. Therefore, the complexity and the manufacturing cost thereof become increased, and the utilization level of the high speed wireless communication becomes decreased.

### SUMMARY OF THE INVENTION

It is, therefore, an object of the present invention to provide an apparatus and method for carrier wave phase recovery and I/Q imbalance compensation in a quadrature demodulating receiver in order to increase the utilization level of wireless communication with a simple structure by integrally embodying the carrier wave recovery function and the I/Q phase imbalance compensation function by firstly compensating one of channels, for example, I-channel, and then compensating the other based on the firstly compensated channel.

In accordance with an aspect of the present invention, there is provided an apparatus for a carrier wave phase recovery and an I(In-phase)/Q(Quadrature-phase) channel phase imbalance compensation, including: a phase error compensating unit for compensating a phase error for a reference channel which is one of the I channel and the Q channel; and a phase imbalance compensation unit for compensating a phase imbalance between the reference channel and a target channel that is the other of the I channel and the Q channel for the target channel based on the reference channel that is the phase error compensated channel at the phase error compensating means.

In accordance with an aspect of the present invention, there is also provided a method for a carrier wave phase recovery and an I(In-phase)/Q(Quadrature-phase) channel phase imbalance compensation, including the steps of: a) compensating a phase error for a reference channel which is one of the I channel and the Q channel; and b) compensating a phase imbalance between the reference channel and a target channel that is the other of the I channel and the 0 channel for the target channel based on the reference channel that is the phase error compensated channel from the step a).

### BRIEF DESCRIPTION OF THE DRAWINGS

The above and other objects and features of the present invention will become better understood with regard to the following description of the preferred embodiments given in conjunction with the accompanying drawings, in which:

FIG. 1 is a block diagram illustrating an apparatus for phase recovery and I/Q imbalance compensation in a quadrature demodulating receiver according to an embodiment of the present invention;

FIG. 2 is a constellation graph of a QPSK signal having an imbalance between I/Q channels according to an embodiment of the present invention; and

FIG. 3 is a block diagram illustrating an apparatus for carrier wave phase recovery and phase imbalance compensation according to an embodiment of the present invention.

### DETAILED DESCRIPTION OF THE INVENTION

Hereinafter, an apparatus and method for phase recovery and I/Q imbalance compensation in a quadrature demodulating receiver will be described in more detail with reference to the accompanying drawings.

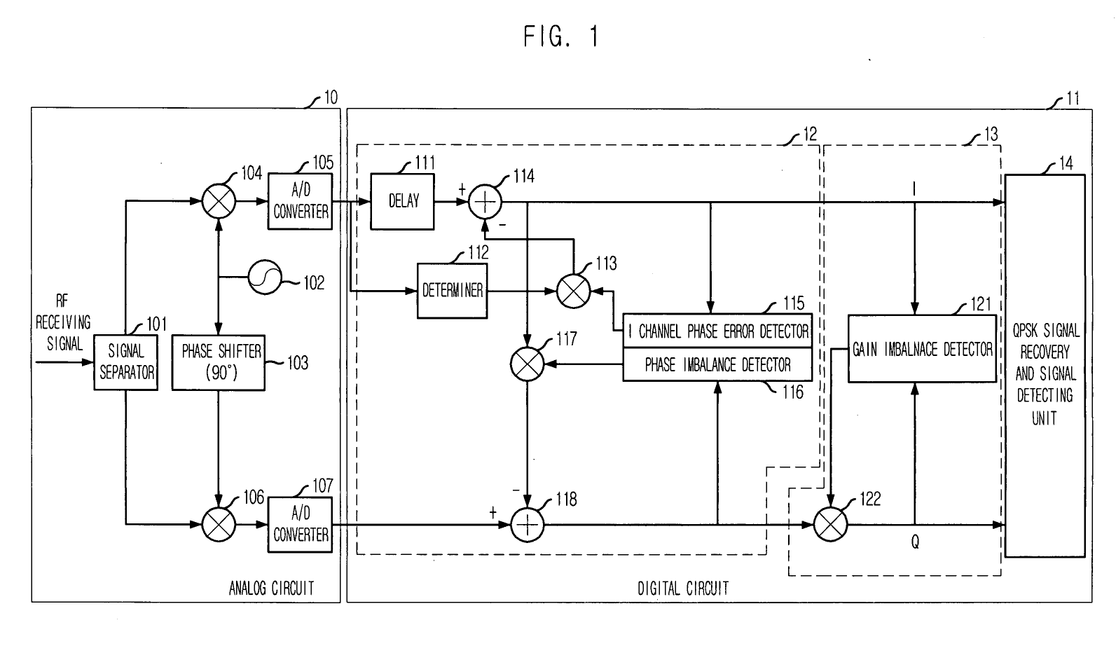

FIG. 1 is a block diagram illustrating an apparatus for phase recovery and I/O imbalance compensation in a quadrature demodulating receiver according to an embodiment of the present invention.

As shown in FIG. 1, the QPSK quadrature demodulating receiver includes an analog circuit 10, and a digital circuit 11. The digital circuit 11 is an apparatus for phase recovery and I/Q imbalance compensation according to the present embodiment. The apparatus for phase recovery and I/O imbalance compensation according to the present embodiment includes a carrier wave phase recovery and an I/Q channel phase imbalance compensating device 12, an I/Q channel gain imbalance compensating device 13, and a QPSK signal recovery and signal detecting device 14.

Herein, an In-phase (I) channel and a quadrature-phase (Q) channel denotes I signal component and Q signal component of a receiving signal that is a complex signal in a quadrature demodulating receiver.

The analog circuit 10 includes a signal separator 101, a carrier wave frequency generator 102, mixers 104 and 106, a phase shifter 103, and analog/digital (A/D) converters 105 and 107. The signal separator 101 receives a radio frequency (RF) signal from an antenna, and transfers the received RF signal to the mixers 104 and 106. The mixer 104 multiplies the RF received signal with the output signal from the carrier wave frequency generator 102, thereby outputting an analog I-channel signal.

After receiving the RF signal from the signal separator 101, the mixer 106 multiplies the RF signal with a phase-shifted signal outputted from the phase shifter 103, thereby outputting an analog Q channel signal.

The A/D converters 105 and 106 convert the analog I/O channel signals to digital I/Q channel signals.

As shown in FIG. 1, in the QPSK quadrature receiver, the sampled signals outputted from the A/D converters 105 and 107 can be expressed as following Eq. 1.
r(k)=(I(k)+j(γI(k)sin φ+γQ(k)cos φ)e^{jφ}+w_{I}(k)+w_{Q}(k)) Eq. 1

In Eq. 1, r(k) denotes a complex receiving signal that is the output of the A/D converter, and I(k) and Q(k) denote the sampled I channel and Q channel signals. W₁(k) and W_{Q}(k) denote noise functions of I channel and Q channel. Y denotes a gain imbalance that is a comparative value of Q channel against I channel. Φ denotes a phase imbalance that is a phase difference between the I-channel and the Q-channel, and θ is a signal phase error. As shown in Eq. 1, a compensation for phase error and phase/gain imbalance is required.

In general, a carrier wave phase recovery circuit such as a phase error compensation circuit, and an I/Q channel imbalance compensation circuit are independently operated according to the related art. In the present invention, the phase error compensation is performed for an I channel, that is, carrier wave phase recovery, by integrating the carrier wave phase recovery circuit and the I/Q imbalance compensation circuit, and the phase imbalance of the Q-channel is compensated based on the I channel value. The phase error compensation controls the I channel signal to have a target intensity. That is, the phase error compensation the difference, that is a phase error, between an I channel signal and target symbol deciding values 1 or −1 for the I channel. Then, the phase imbalance of the Q-channel is compensated based on the corrected I channel.

The general phase error compensation function the phase error of the I channel and the Q channel identically. However, in the present invention, a phase error signal for an I channel is detected first, then, the phase imbalance for the Q channel is corrected based on the compensated I channel. In order to compensate the phase error, a detector for I channel is given as following Eq. 2.
b(k)=I(k)−Î(k) Eq. 2

In Eq. 2, I(k) denotes an I channel signal, Î(k) denotes a decided value, for example, 1 or −1, as an I channel signal, and b(k) denotes a phase error of I channel signal.

In order to correct the phase error of the digital I channel signal outputted from the A/D converter 105, an I channel phase error detector 115 detects an I channel phase error that is a difference between target signals 1, or −1 of the I channel signal.

The detected I channel phase error, which is the output of the I channel phase error detector 115, is multiplied with the output of the determiner 112 that decides the I channel signal value in the output signal of the A/D converter 105. Then, a subtractor 114 subtracts the output of a multiplier 113 from the output of a delay 111 which delays the I channel signal as much as one symbol. The result of subtracting inputs to the I channel phase error detector 115 again. The I channel phase error is corrected through the above described operations.

A phase imbalance detector 116 detects a phase imbalance between the I channel signal with the phase error compensated as descried above, and the Q channel signal. Then, phase imbalance compensators 117 and 118 compensate the detected phase imbalance between the I/Q channels.

Then, a gain imbalance detector 121 detects a gain imbalance between the phase imbalance corrected I/Q channels, and a gain imbalance compensator 122 corrects the gain imbalance between the I/Q channels by removing the gain imbalance value from the Q channel signal value. After correcting, the QPSK signal recovery and signal detecting unit 14 restores a target signals from the corrected signal outputted from the gain imbalance compensating unit 122.

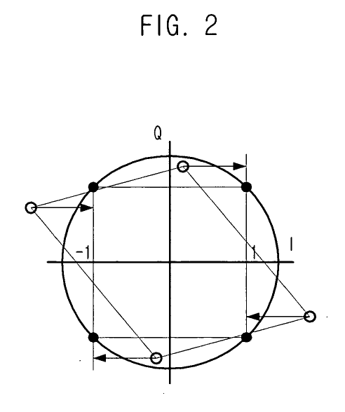

FIG. 2 is a constellation graph of a QPSK signal having an imbalance between I/Q channels according to an embodiment of the present invention. That is, the constellation graph of FIG. 2 shows a signal having a phase error, a phase and gain imbalance between I/O channels.

Referring to FIG. 2, a dot (●) denotes the constellation of a target signal, and a circle (◯) denotes a signal having a phase error or a phase and gain imbalance between I/Q channels. A distance between the circle signal and the dot signal is measured, and the circle signal is shifted as much as the measured distance to compensate the phase error and the phase/gain imbalance.

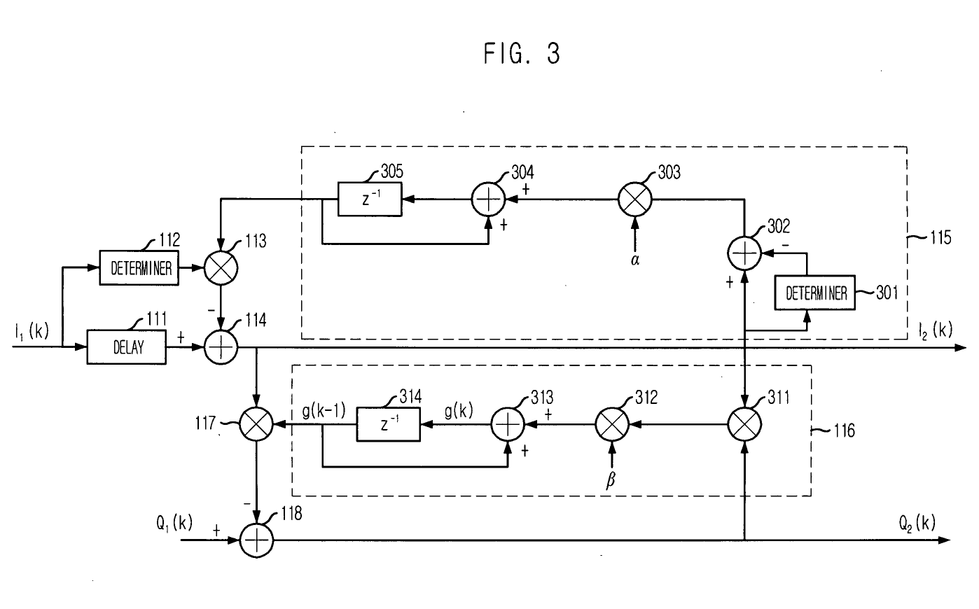

FIG. 3 is a block diagram illustrating an apparatus for carrier wave phase recovery and phase imbalance compensation according to an embodiment of the present invention. Particularly, FIG. 3 shows the phase error detector 115 and the phase imbalance detector 116 in detail. Hereinafter, a method for carrier wave phase recovery and phase imbalance compensation will be also described.

As shown in FIG. 3, the apparatus for carrier wave phase recovery and phase imbalance compensation according to the present embodiment includes a phase error compensator and a phase imbalance compensator. Herein, the phase error compensator includes a phase error detector, a loop filter, and a phase error compensator. The phase error detector is formed of a decider 301 and an adder 302, and the loop filter is formed of a multiplier 303, an adder 304 and a delay 305. The error compensator formed of a delay 111, a determiner 112, a multiplier 113 and a subtractor 114. The phase imbalance compensator includes a phase imbalance detector 116 for detecting a phase imbalance value, and a phase imbalance compensator for removing the phase imbalance value. The phase imbalance is formed of a multiplier 117 and an adder 118.

The subtractor 302 generates the phase error of I channel by subtracting the output of the determiner 301 from the I channel input signal that is the output signal from the phase error compensator 114. The generated I channel phase errors are accumulated through the loop filters 303, 304 and 305. Herein, the multiplier 303 multiplies a loop gain α of the loop filters 303, 304 and 305, thereby deciding the operating range of the loop filter.

The adder 304 adds the output from the delay 305 to the output of the multiplier 303. That is, the adder 304 adds the phase error of a previous sample output from the delay 305 with the phase error of a current sample output from the multiplier 303.

The multiplier 113 multiplies the accumulated phase error outputted from the loop filter with the output of the determiner 112, and the subtractor 114 removes the phase error from the I channel signal by subtracting the output of the multiplier 113 from the output of the sample delay 111 that delays the I channel signal inputted from the determiner 112.

Hereinafter, the phase imbalance compensation between I/O channels after compensating a phase error will be described.

As shown in FIG. 3, the phase imbalance detector for detecting a phase imbalance includes multipliers 311 and 312, a subtractor 313 and a delay 314, and the phase imbalance compensator for compensating the detected phase imbalance includes a multiplier 117 and an adder 116.

e(k) denotes an error signal that is a result of multiplying an I channel signal and a 0 channel signal, and β denotes a loop gain of a filter. The loop gain has a fixed value regardless of the error signal.

The multiplier 311 generates an error signal e(k) by multiplying an input signal I₂(k) and a signal Q₁(k), where the error signal I₂(k) is a phase error compensated signal outputted from the subtractor 114 and the signal Q₁(k) is the output signal of the subtractor 118. The multiplier 312 multiplier 312 multiplies the error signal e(k) with a loop gain value β. An integrator formed of the subtractor 313 and the delay 314 detects the phase imbalance g(k-1) between the I channel and the Q channel from the output of the multiplier 312.

The multiplier 312 multiplies the error signal e(k) outputted from the multiplier 311 with the loop gain value β, the adder 313 adds the multiplying result with a previously obtained phase imbalance, and the delay 314 delays the adding result as long as one sample. Then, the multiplier 117 multiplies the delayed adding result with the output of the subtractor 114, thereby outputting the phase imbalance.

The subtractor 118 removes the phase imbalance of the Q channel against the I channel by subtracting the phase imbalance value outputted from the multiplier 117 from the Q channel.

As described above, the apparatus and method for phase/gain imbalance compensation according to the present embodiment was described with the I channel as the reference channel and the Q channel as the target channel for phase/gain imbalance compensating target. However, the apparatus and method for phase/gain imbalance compensation according to the present invention can be identically applied when the Q channel is used as the reference channel and the I channel is used as the target channel for the phase/gain imbalance compensation. In this case, a phase/gain imbalance between the I channel and the Q channel is detected, and a phase/gain imbalance is removed from the I channel using the detected phase/gain imbalance because the Q channel is the reference channel.

The above described method according to the present invention can be embodied as a program and stored on a computer readable recording medium. The computer readable recording medium is any data storage device that can store data which can be thereafter read by the computer system. The computer readable recording medium includes a read-only memory (ROM), a random-access memory (RAM), a CD-ROM, a floppy disk, a hard disk and an optical magnetic disk.

As described above, the an apparatus and method for phase recovery and I/Q imbalance compensation according to the present invention can prevent the performance of a demodulator from being degraded due to the phase imbalance between the I channel and the Q channel by detecting the phase imbalance between the I channel and the Q channel and compensating the detected phase imbalance.

The apparatus and method for phase recovery and I/O imbalance compensation according to the present invention removes the phase imbalance between the I channel and the Q channel, which may be generated in the QPSK quadrature demodulator in a high speed wireless communication system using an adaptive loop. Also, the apparatus and method according to the present invention can detect the phase error of the I channel using the difference between symbol determining values of a signal used for the phase imbalance detection and compensates the phase imbalance between the I channel and the Q channel using the same.

The apparatus and method for phase recovery and I/Q imbalance compensation according to the present invention can compensate the phase imbalance and the phase error with a simple circuit structure by integrally embodying the phase error compensation function and the I/Q channel phase imbalance compensation function. That is, the apparatus and method according to the present invention performs the phase error compensation for the I channel and then compensates the phase imbalance of the Q channel using the phase error compensated I channel value as a reference. Therefore, the utilization level of the high speed wireless communication can be improved.

The present application contains subject matter related to Korean patent application Nos. KR 2005-116154 and 2006-69954, filed with the Korean Intellectual Property office on Dec. 1, 2005, and Jul. 25, 2006, the entire contents of which being incorporated herein by reference.

While the present invention has been described with respect to certain preferred embodiments, it will be apparent to those skilled in the art that various changes and modifications may be made without departing from the spirits and scope of the invention as defined in the following claims.

What is claimed is:

1. An apparatus for a carrier wave phase recovery and an I(In-phase)/Q(Quadrature-phase) channel phase imbalance compensation, comprising:
a phase error compensating means for compensating a phase error for a reference channel which is one of the I channel and the Q channel; and
a phase imbalance compensation means for compensating a phase imbalance between the reference channel and a target channel that is the other of the I channel and the Q channel for the target channel based on the reference channel that is the phase error compensated channel at the phase error compensating means.

2. The apparatus as recited in claim 1, wherein the phase error compensating means includes:
a phase error detecting means for obtaining a phase error signal by subtracting a corresponding symbol determining value from a signal of the reference channel;
a loop filter for accumulating the detected phase error; and
an error compensating means for compensating a phase error of the reference channel using the accumulated phase error value outputted from the loop filter.

3. The apparatus as recited in claim 1, wherein the phase imbalance compensating means includes:
a phase imbalance detecting means for obtaining a phase imbalance error signal by multiplying the phase error compensated reference channel at the phase error compensating means and the target channel, and detecting a phase imbalance by multiplying a predetermined loop gain to the phase imbalance error signal, and integrating the multiplying result; and
a compensating means for compensating a phase imbalance by multiplying the detected phase imbalance and the phase error compensated reference channel and subtracting the multiplying result from the target channel.

4. The apparatus as recited in claim 3, wherein the reference channel is an In-phase (I) channel, and the target channel is a Quadrature-phase (Q) channel.

5. A method for a carrier wave phase recovery and an I(In-phase)/Q(Quadrature-phase) channel phase imbalance compensation, comprising the steps of:
a) compensating a phase error for a reference channel which is one of the I channel and the Q channel; and
b) compensating a phase imbalance between the reference channel and a target channel that is the other of the I channel and the Q channel for the target channel based on the reference channel that is the phase error compensated channel from the step a).

6. The method as recited in claim 5, wherein the step a) includes the steps of:
a-1) obtaining a phase error signal by subtracting a corresponding symbol determining value from a signal of the reference channel;
a-2) accumulating the detected phase error; and
a-3) compensating a phase error of the reference channel using the accumulated phase error value outputted from the step a-2).

7. The method as recited in claim 5, wherein the step b) includes the steps of:
b-1) obtaining a phase imbalance error signal by multiplying the phase error compensated reference channel from the step a) and the target channel;
b-2) detecting a phase imbalance by multiplying a predetermined loop gain to the phase imbalance error signal, and integrating the multiplying result; and
b-3) compensating a phase imbalance by multiplying the detected phase imbalance and the phase error compensated reference channel from the step a) and subtracting the multiplying result from the target channel.

8. The method as recited in claim 7, wherein the reference channel is an In-phase (I) channel, and the target channel is a Ouadrature-phase (Q) channel.
